(19) United States
(12) Patent Application Publication
(10) Pub. No.: US 2025/0254846 A1
(43) Pub. Date: Aug. 7, 2025

(54) APPARATUSES AND METHODS FOR USING NANOFLUID COOLANT WITH FERRITE NANOPARTICLES FOR MAGNETIC BLOCKING AND COOLING

(71) Applicant: Toyota Motor Engineering and Manufacturing North America, Inc., Plano, TX (US)

(72) Inventors: Yanghe Liu, Ann Arbor, MI (US); Shailesh N. Joshi, Ann Arbor, MI (US)

(73) Assignees: Toyota Motor Engineering and Manufacturing North America, Inc., Plano, TX (US); Toyota Jidosha Kabushiki Kaisha, Toyota-shi (JP)

(21) Appl. No.: 18/431,672

(22) Filed: Feb. 2, 2024

(51) Int. Cl. H05K 7/20; H01F 1/34; H02J 50/10

(52) U.S. Cl. CPC H05K 7/20927; H01F 1/344; H02J 50/10; H05K 7/20272

(57) ABSTRACT

An apparatus and method for cooling a wireless power transfer (WPT) transmitter coil. The apparatus may include a reservoir holding coolant. The apparatus may further include a coolant loop, wherein the coolant loop may include a plurality of heat sinks. The apparatus may further include a pump. The apparatus may further include a WPT transmitter coil, wherein coolant flows from the reservoir through the coolant loop into the plurality of heat sinks via the pump, wherein heat from the WPT transmitter coil is transferred from the plurality of heat sinks to the coolant.

### BACKGROUND

Wireless inductive charging systems for electric vehicles (EVs) generally include a receiver and rectifier to transfer power from a magnetic or electromagnetic field, applied in the vicinity of the receiver, to provide electric power for the electric vehicles. The receiver is typically placed or mounted on the bottom of the electric vehicle (EV) such that a transmitter can be placed in proximity to the receiver to expose the receiver to a changing magnetic field. Printed Circuit Board (PCB) based coils may be used for the wireless power transfer.

### SUMMARY

In one example implementation, an apparatus for cooling a wireless power transfer (WPT) transmitter coil may include but is not limited to a reservoir holding coolant. The apparatus may further include a coolant loop, wherein the coolant loop may include a plurality of heat sinks. The apparatus may further include a pump. The apparatus may further include a WPT transmitter coil, wherein coolant flows from the reservoir through the coolant loop into the plurality of heat sinks via the pump, wherein heat from the WPT transmitter coil is transferred from the plurality of heat sinks to the coolant.

One or more of the following example features may be included. The coolant may include nano ferrite particles. The nano ferrite particles may include at least one of Mn—Zn, cobalt ferrite, barium ferrite, and nickel-zinc. A magnetic field of the WPT transmitter coil may assist in pumping the coolant. The apparatus may further include a metering valve in an inlet tube of the coolant loop. The apparatus may further comprise an electromagnet proximate an inlet of a manifold. A magnetic field magnitude difference between the inlet and an outlet may cause the coolant with the nano ferrite particles to flow passively from the inlet to the outlet.

In another example implementation, a cooling apparatus for cooling a wireless power transfer (WPT) transmitter coil may include but is not limited to a reservoir for holding coolant. The apparatus may further include a coolant loop, wherein the coolant loop may include a plurality of heat sinks. The apparatus may further include an electromagnet proximate an inlet of a manifold. The apparatus may further include a WPT transmitter coil, wherein coolant may flow from the reservoir through the coolant loop into the plurality of heat sinks, wherein a magnetic field magnitude difference between the inlet and an outlet may cause the coolant to flow passively from the inlet to the outlet, wherein heat from the WPT transmitter coil may be transferred from the plurality of heat sinks to the coolant.

One or more of the following example features may be included. The coolant may include nano ferrite particles. The nano ferrite particles may include at least one of Mn—Zn and cobalt ferrite. The nano ferrite particles may include at least one of barium ferrite and nickel-zinc. A magnetic field of the WPT transmitter coil may assist in pumping the coolant. The apparatus may further include a metering valve in an inlet tube of the coolant loop. The apparatus may further include a pump that may help the coolant to flow.

In another example implementation, a method for cooling a wireless power transfer (WPT) transmitter coil may include but is not limited to holding coolant in a reservoir. A coolant loop that may include a plurality of heat sinks may be connected to the reservoir. Coolant from the reservoir may be moved through the coolant loop into the plurality of heat sinks. Heat may be transferred from a WPT transmitter coil to the coolant via the plurality of heat sinks.

One or more of the following example features may be included. The coolant may include nano ferrite particles. The nano ferrite particles may include at least one of Mn—Zn, cobalt ferrite, barium ferrite, and nickel-zinc. A magnetic field of the WPT transmitter coil may assist in pumping the coolant. A metering valve may be opened in an inlet tube of the coolant loop. A magnetic field may be generated via an electromagnet proximate an inlet of a manifold, wherein a magnetic field magnitude difference between the inlet and an outlet may cause the coolant with the nano ferrite particles to flow passively from the inlet to the outlet.

The details of one or more example implementations are set forth in the accompanying drawings and the description below. Other possible example features and/or possible example advantages will become apparent from the description, the drawings, and the claims. Some implementations may not have those possible example features and/or possible example advantages, and such possible example features and/or possible example advantages may not necessarily be required of some implementations.

### BRIEF DESCRIPTION OF DRAWINGS

FIG. 1 is an example diagrammatic view of a cooling apparatus according to one or more example implementations of the disclosure; and

FIG. 2 is an example diagrammatic view of a screen image displayed by a cooling process according to one or more example implementations of the disclosure.

Like reference symbols in the various drawings may indicate like elements.

### DESCRIPTION

Wireless inductive charging systems for electric vehicles (EVs) generally include a receiver and rectifier to transfer power from a magnetic or electromagnetic field, applied in the vicinity of the receiver, to provide electric power for the electric vehicles. The receiver is typically placed or mounted on the bottom of the electric vehicle (EV) such that a transmitter can be placed in proximity to the receiver to expose the receiver to a changing magnetic field. Printed Circuit Board (PCB) based coils may be used for the wireless power transfer (WPT). A cooling system may be used to help cool devices involved in the WPT. For instance, a self-pumping magnetic cooling device that employs Mn—Zn ferrite nanoparticles suspended in water and does not require external energy input may be used; however, as will be discussed in greater detail below, the present disclosure may use a ferrite nanofluid (e.g., Mn—Zn ferrite nanoparticles) to cool a WPT transmitter coil embedded in concrete. The coolant with nano ferrite particles may be pumped using the magnetic field from a WPT transmitter coil.

In some implementations, the present disclosure may be embodied as a method, system/apparatus, or computer program product. Accordingly, in some implementations, the present disclosure may take the form of an entirely hardware implementation, an entirely software implementation (including firmware, resident software, micro-code, etc.) or an implementation combining software and hardware aspects that may all generally be referred to herein as a “circuit,” “module” or “system.” Furthermore, in some implementations, the present disclosure may take the form of a computer program product on a computer-usable storage medium having computer-usable program code embodied in the medium.

In some implementations, electronic circuitry including, for example, programmable logic circuitry, an application specific integrated circuit (ASIC), gate arrays such as field-programmable gate arrays (FPGAs) or other hardware accelerators, micro-controller units (MCUs), or programmable logic arrays (PLAs), integrated circuits (ICs), digital circuit elements, analog circuit elements, combinational logic circuits, digital signal processors (DSPs), complex programmable logic devices (CPLDs), etc. may execute the computer readable program instructions/code by utilizing state information of the computer readable program instructions to personalize the electronic circuitry, in order to perform aspects of the present disclosure. Multiple components of the hardware may be integrated, such as on a single die, in a single package, or on a single printed circuit board or logic board. For example, multiple components of the hardware may be implemented as a system-on-chip. A component, or a set of integrated components, may be referred to as a chip, chipset, chiplet, or chip stack. Examples of a system-on-chip include a radio frequency (RF) system-on-chip, an artificial intelligence (AI) system-on-chip, a video processing system-on-chip, an organ-on-chip, a quantum algorithm system-on-chip, etc.

Examples of processing hardware may include, e.g., a central processing unit (CPU), a graphics processing unit (GPU), an approximate computing processor, a quantum computing processor, a parallel computing processor, a neural network processor, a signal processor, a digital processor, an analog processor, a data processor, an embedded processor, a microprocessor, and a co-processor. The co-processor may provide additional processing functions and/or optimizations, such as for speed or power consumption. Examples of a co-processor include a math co-processor, a graphics co-processor, a communication co-processor, a video co-processor, and an artificial intelligence (AI) co-processor.

In some implementations, the flowchart and block diagrams in the figures illustrate the architecture, functionality, and operation of possible implementations of apparatus (e.g., systems), methods and computer program products according to various implementations of the present disclosure. Each block in the flowchart and/or block diagrams, and combinations of blocks in the flowchart and/or block diagrams, may represent a module, segment, or portion of code, which comprises one or more executable computer program instructions for implementing the specified logical function(s)/act(s). These computer program instructions may be provided to a processor of a general purpose computer, special purpose computer, or other programmable data processing apparatus to produce a machine, such that the computer program instructions, which may execute via the processor of the computer or other programmable data processing apparatus, create the ability to implement one or more of the functions/acts specified in the flowchart and/or block diagram block or blocks or combinations thereof. It should be noted that, in some implementations, the functions noted in the block(s) may occur out of the order noted in the figures (or combined or omitted). For example, two blocks shown in succession may, in fact, be executed substantially concurrently, or the blocks may sometimes be executed in the reverse order, depending upon the functionality involved.

In some implementations, these computer program instructions may also be stored in a computer-readable memory that can direct a computer or other programmable data processing apparatus to function in a particular manner, such that the instructions stored in the computer-readable memory produce an article of manufacture including instruction means which implement the function/act specified in the flowchart and/or block diagram block or blocks or combinations thereof.

In some implementations, the computer program instructions may also be loaded onto a computer or other programmable data processing apparatus to cause a series of operational steps to be performed (not necessarily in a particular order) on the computer or other programmable apparatus to produce a computer implemented process such that the instructions which execute on the computer or other programmable apparatus provide steps for implementing the functions/acts (not necessarily in a particular order) specified in the flowchart and/or block diagram block or blocks or combinations thereof.

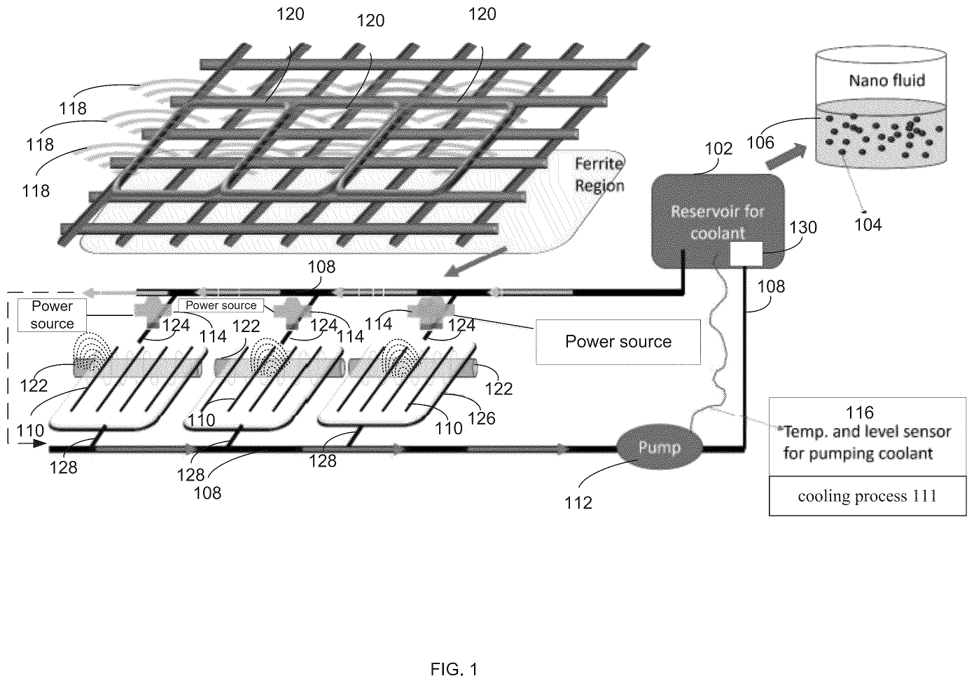

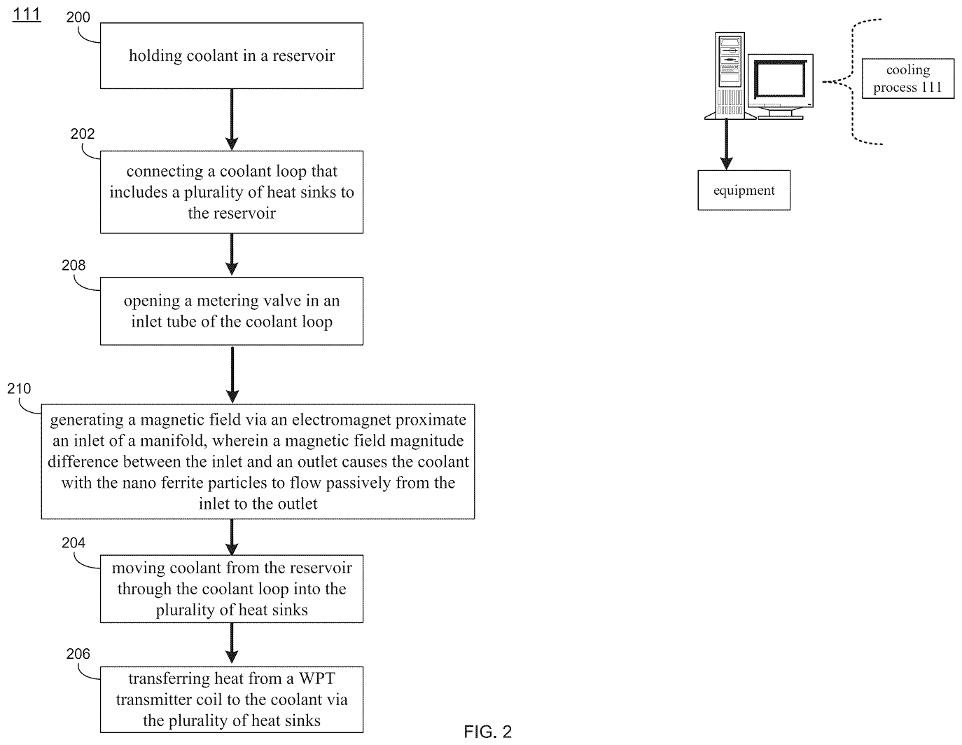

As discussed above and referring also at least to the example implementations of FIGS. 1-2, a cooling apparatus (e.g., cooling apparatus 100) for cooling a wireless power transfer (WPT) transmitter coil may include a reservoir holding coolant. The apparatus may further include a coolant loop, wherein the coolant loop may include a plurality of heat sinks. The apparatus may further include a pump. The apparatus may further include a WPT transmitter coil, wherein coolant flows from the reservoir through the coolant loop into the plurality of heat sinks via the pump, wherein heat from the WPT transmitter coil is transferred from the plurality of heat sinks to the coolant.

In some implementations, a cooling apparatus (e.g., cooling apparatus 100) for cooling a wireless power transfer (WPT) transmitter coil may include a reservoir holding coolant. For instance, and referring to the example implementation of FIG. 1, cooling apparatus 100 is shown with a reservoir (e.g., reservoir 102) for holding coolant (e.g., coolant 106). In some implementations, coolant 106 may include nano ferrite particles (e.g., nano ferrite particles 104). In some implementations, nano ferrite particles 104 may include at least one of Mn—Zn, cobalt ferrite, barium ferrite, and/or nickel-zinc. In some implementations, nano ferrite particles 104 may be obtained from recycled materials, and as will be discussed in greater detail below, may be used for magnetic flux. It will be appreciated after reading the present disclosure that any other examples of nano ferrite particles 104 may be used without departing from the scope of the present disclosure.

In some implementations, cooling apparatus 100 may further include a coolant loop, wherein the coolant loop may include a plurality of heat sinks. For instance, cooling apparatus 100 may include a coolant loop (e.g., coolant loop 108) that includes a plurality of heat sinks (e.g., heat sink 110). Heat sink 110 may be part of the manifold. In some implementations, cooling apparatus 100 may further include a metering valve in an inlet tube of the coolant loop. For instance, in some implementations, for each heat sink 110, there may be a metering valve (e.g., metering valve 114) placed in the inlet tube. In some implementations, metering valve 114 may be connected to one or more power sources (e.g., a battery). As will be discussed in greater detail below, when there is vehicle that needs charging (as determined by one or more sensors, such as sensor 116), metering valve 114 may be opened for coolant flow. In some implementations, sensor 116 may include cooling process 111, which may use the temperature and/or battery level sensor to communicate with metering valve 114 to open and close. For instance, based upon the temperature and/or battery level being at a threshold(s), cooling process 111 may open and close metering valve 114. As another example, if the reservoir coolant temperature is higher than a preset temperature, e.g., 65 degrees C. (a typical electronics coolant temperature), the pump may increase to increase the flow rate, to increase the heat transfer for lowering the coolant temperature. Other sensors may include, e.g., electrical type sensors that are connected to the transmitter pads. If the traffic is crowded and a lot of vehicles are being charged, most of the transmitter pads are being activated at the same time. The pump power may thus be increased to make sure the coolant is enough for all activated pads. This function may be triggered by the current sensors in the main power bus.

In some implementations, cooling apparatus 100 may further include a pump. For instance, cooling apparatus 100 may include a pump (e.g., pump 112). As will be discussed in greater detail below, in some implementations, a magnetic field (e.g., magnetic field 118) of a WPT transmitter coil (e.g., WPT transmitter coil 120) may assist in pumping the coolant. In some implementations, cooling apparatus 100 may further include an electromagnet (e.g., electromagnet 122) proximate an inlet (e.g., inlet 124) of a manifold (e.g., manifold 126), which in some implementations may be non-metal with built-in fins. That is, electromagnet 122 may be placed near the inlet of the manifold to generate an extra magnetic field for its location, and the extra electromagnet will be energized for driving coolant 106 using nano ferrite particles 104. In some implementations, a magnetic field magnitude difference between inlet 124 and an outlet (e.g., outlet 128) may cause the coolant with the nano ferrite particles to flow passively from the inlet to the outlet. As such, due to the magnetic field magnitude difference between inlet 124 and outlet 128, coolant 106 (using nano ferrite particles 104) will flow from inlet 124 to outlet 128 passively.

As a result, in some implementations, cooling apparatus 100 may further include WPT transmitter coil 120, wherein coolant 106 flows from reservoir 102 through coolant loop 108 into the plurality of heat sinks 110 via pump 112, wherein heat from WPT transmitter coil 120 is transferred from the plurality of heat sinks 110 to coolant 106. That is, using the interaction between the magnetic fields and nano ferrite particles 104, coolant 106 (using nano ferrite particles 104) flows from reservoir 102 and through coolant loop 108 into heat sinks 110 where heat from WPT transmitter coil 120 is transferred to coolant 106. Also, the magnetic field(s) of the WPT transmitter coil may assist in pumping the coolant. In some implementations, the magnetic field magnitude difference between inlet 124 and outlet 128 may be sufficient to have coolant 106 flow from inlet 124 to outlet 128 passively without the need for pump 112.

In some implementations, reservoir 102 may include a heat exchanger (e.g., heat exchanger 130). In some implementations, heat exchanger 130 may be used to transfer heat between two or more liquids (e.g., liquids prior to reservoir 102 and liquids after reservoir 102).

As discussed above and referring also at least to the example implementations of FIGS. 1-2, cooling process 111 may hold 200 coolant in a reservoir. In some implementations, cooling process 111 may connect 202 a coolant loop that may include a plurality of heat sinks to the reservoir. In some implementations, cooling process 111 may move 204 coolant from the reservoir through the coolant loop into the plurality of heat sinks. In some implementations, cooling process 111 may transfer 206 heat from a WPT transmitter coil to the coolant via the plurality of heat sinks. In some implementations, cooling process 111 may open 208 a metering valve in an inlet tube of the coolant loop. In some implementations, cooling process 111 may generate 210 a magnetic field via an electromagnet proximate an inlet of a manifold, wherein a magnetic field magnitude difference between the inlet and an outlet may cause the coolant with the nano ferrite particles to flow passively from the inlet to the outlet.

It will be appreciated after reading the present disclosure that any standard assembly/printing/fabrication, etc. equipment, as well as any other necessary equipment, may be used singly or in any combination with cooling process 111, which may be operatively connected to a computing device, such as the computing device shown in FIG. 2, to obtain their instructions for creating and/or executing one or more aspects of the present disclosure. In one or more example implementations, the respective flowcharts may be manually-implemented, computer-implemented, or a combination thereof

The terminology used herein is for the purpose of describing particular implementations only and is not intended to be limiting of the disclosure. As used herein, the singular forms “a”, “an” and “the” are intended to include the plural forms as well, including any steps performed by a/the computer/processor, unless the context clearly indicates otherwise. As used herein, the phrase “at least one of A, B, and C” should be construed to mean a logical (A OR B OR C), using a non-exclusive logical OR, and should not be construed to mean “at least one of A, at least one of B, and at least one of C.” As another example, the language “at least one of A and B” (and the like) as well as “at least one of A or B” (and the like) should be interpreted as covering only A, only B, or both A and B, unless the context clearly indicates otherwise. It will be further understood that the terms “comprises” and/or “comprising,” when used in this specification, specify the presence of stated features, integers, steps (not necessarily in a particular order), operations, elements, and/or components, but do not preclude the presence or addition of one or more other features, integers, steps (not necessarily in a particular order), operations, elements, components, and/or groups thereof. Example sizes/models/values/ranges can have been given, although examples are not limited to the same.

The terms (and those similar to) “coupled,” “attached,” “connected,” “adjoining,” “transmitting,” “receiving,” “connected,” “engaged,” “coupled,” “adjacent,” “next to,” “on top of,” “above,” “below,” “abutting,” and “disposed,” used herein is to refer to any type of relationship, direct or indirect, between the components in question, and is to apply to electrical, mechanical, fluid, optical, electromagnetic, electromechanical, or other connections. Additionally, the terms “first,” “second,” etc. are used herein only to facilitate discussion, and carry no particular temporal or chronological significance unless otherwise indicated. The terms “cause” or “causing” means to make, force, compel, direct, command, instruct, and/or enable an event or action to occur or at least be in a state where such event or action is to occur, either in a direct or indirect manner. The term “set” does not necessarily exclude the empty set—in other words, in some circumstances a “set” may have zero elements. The term “non-empty set” may be used to indicate exclusion of the empty set—that is, a non-empty set must have one or more elements, but this term need not be specifically used. The term “subset” does not necessarily require a proper subset. In other words, a “subset” of a first set may be coextensive with (equal to) the first set. Further, the term “subset” does not necessarily exclude the empty set—in some circumstances a “subset” may have zero elements.

The corresponding structures, materials, acts, and equivalents (e.g., of all means or step plus function elements) that may be in the claims below are intended to include any structure, material, or act for performing the function in combination with other claimed elements as specifically claimed. While the disclosure describes structures corresponding to claimed elements, those elements do not necessarily invoke a means plus function interpretation unless they explicitly use the signifier “means for.” Unless otherwise indicated, recitations of ranges of values are merely intended to serve as a shorthand way of referring individually to each separate value falling within the range, and each separate value is hereby incorporated into the specification as if it were individually recited. While the drawings divide elements of the disclosure into different functional blocks or action blocks, these divisions are for illustration only. According to the principles of the present disclosure, functionality can be combined in other ways such that some or all functionality from multiple separately-depicted blocks can be implemented in a single functional block; similarly, functionality depicted in a single block may be separated into multiple blocks. Unless explicitly stated as mutually exclusive, features depicted in different drawings can be combined consistent with the principles of the present disclosure.

The description of the present disclosure has been presented for purposes of illustration and description but is not intended to be exhaustive or limited to the disclosure in the form disclosed. After reading the present disclosure, many modifications, variations, substitutions, and any combinations thereof will be apparent to those of ordinary skill in the art without departing from the scope and spirit of the disclosure. The implementation(s) were chosen and described in order to explain the principles of the disclosure and the practical application, and to enable others of ordinary skill in the art to understand the disclosure for various implementation(s) with various modifications and/or any combinations of implementation(s) as are suited to the particular use contemplated. The features of any dependent claim may be combined with the features of any of the independent claims or other dependent claims.

Having thus described the disclosure of the present application in detail and by reference to implementation(s) thereof, it will be apparent that modifications, variations, and any combinations of implementation(s) (including any modifications, variations, substitutions, and combinations thereof) are possible without departing from the scope of the disclosure defined in the appended claims.

What is claimed is:

1. A cooling apparatus comprising:
a reservoir for holding coolant;
a coolant loop, wherein the coolant loop includes a plurality of heat sinks;
a pump; and
a wireless power transfer (WPT) transmitter coil, wherein coolant flows from the reservoir through the coolant loop into the plurality of heat sinks via the pump, wherein heat from the WPT transmitter coil is transferred from the plurality of heat sinks to the coolant.

2. The cooling apparatus of claim 1, wherein the coolant includes nano ferrite particles.

3. The cooling apparatus of claim 2, wherein the nano ferrite particles include at least one of Mn—Zn, cobalt ferrite, barium ferrite, and nickel-zinc.

4. The cooling apparatus of claim 1, wherein a magnetic field of the WPT transmitter coil assists in pumping the coolant.

5. The cooling apparatus of claim 1 further comprising a metering valve in an inlet tube of the coolant loop.

6. The cooling apparatus of claim 2 further comprising an electromagnet proximate an inlet of a manifold.

7. The cooling apparatus of claim 6, wherein a magnetic field magnitude difference between the inlet and an outlet causes the coolant with the nano ferrite particles to flow passively from the inlet to the outlet.

8. A cooling apparatus for cooling a wireless power transfer (WPT) transmitter coil comprising:
a reservoir for holding coolant;
a coolant loop, wherein the coolant loop includes a plurality of heat sinks;
an electromagnet proximate an inlet of a manifold; and
a WPT transmitter coil, wherein coolant flows from the reservoir through the coolant loop into the plurality of heat sinks, wherein a magnetic field magnitude difference between the inlet and an outlet causes the coolant to flow passively from the inlet to the outlet, wherein heat from the WPT transmitter coil is transferred from the plurality of heat sinks to the coolant.

9. The cooling apparatus of claim 8, wherein the coolant includes nano ferrite particles.

10. The cooling apparatus of claim 9, wherein the nano ferrite particles include at least one of Mn—Zn and cobalt ferrite.

11. The cooling apparatus of claim 9, wherein the nano ferrite particles include at least one of barium ferrite and nickel-zinc.

12. The cooling apparatus of claim 8, wherein a magnetic field of the WPT transmitter coil assists in pumping the coolant.

13. The cooling apparatus of claim 8 further comprising a metering valve in an inlet tube of the coolant loop.

14. The cooling apparatus of claim 8 further comprising a pump that helps the coolant to flow.

15. A method for cooling a wireless power transfer (WPT) transmitter coil comprising: holding coolant in a reservoir;
connecting a coolant loop that includes a plurality of heat sinks to the reservoir;
moving coolant from the reservoir through the coolant loop into the plurality of heat sinks; and
transferring heat from a WPT transmitter coil to the coolant via the plurality of heat sinks.

16. The method of claim 15, wherein the coolant includes nano ferrite particles.

17. The method of claim 16, wherein the nano ferrite particles include at least one of Mn—Zn, cobalt ferrite, barium ferrite, and nickel-zinc.

18. The method of claim 15, wherein a magnetic field of the WPT transmitter coil assists in pumping the coolant.

19. The method of claim 15 further comprising opening a metering valve in an inlet tube of the coolant loop.

20. The method of claim 16 further comprising generating a magnetic field via an electromagnet proximate an inlet of a manifold, wherein a magnetic field magnitude difference between the inlet and an outlet causes the coolant with the nano ferrite particles to flow passively from the inlet to the outlet.
